(19) United States
(12) Patent Application Publication
(10) Pub. No.: US 2026/0290485 A1
(43) Pub. Date: Sep. 24, 2026

(54) REPAIRING LANES ASSOCIATED WITH MEMORY DEVICES

(71) Applicant: Micron Technology, Inc., Boise, ID (US)

(72) Inventor: Woo Hyun PAIK, Suwanee, GA (US)

(21) Appl. No.: 19/454,790

(22) Filed: Jan. 21, 2026

Related U.S. Application Data
(60) Provisional application No. 63/775,516, filed on Mar. 21, 2025.

(51) Int. Cl. G11C 29/44

(52) U.S. Cl. CPC G11C 29/44

(57) ABSTRACT

Implementations described herein relate to repairing lanes associated with memory devices. In some implementations, a memory device may detect, using a lane repair block, that a lane of the memory device is associated with a lane failure, wherein the lane repair block is employed prior to a first physical (PHY) latch that is between a through-silicon via (TSV) associated with the memory device and a data queue (DQ) pad associated with the memory device. The memory device may map, using the lane repair block, the lane associated with the lane failure to an alternate lane associated with one or more alternate blocks.

### CROSS-REFERENCE TO RELATED APPLICATION

This Patent Application claims priority to U.S. Provisional Patent Application No. 63/775,516, filed on Mar. 21, 2025, entitled “REPAIRING LANES ASSOCIATED WITH MEMORY DEVICES,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to repairing lanes associated with memory devices.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of repairing lanes associated with memory devices.

FIG. 2 is a diagrammatic view of an example memory device.

FIGS. 3A-3B are diagrams of examples of existing data flows with lane repair.

FIG. 4 is a diagram of an example of lane repair prior to physical latches.

FIG. 5 is a diagram of an example associated with lane repairing.

FIG. 6 is a flowchart of an example method associated with repairing lanes associated with memory devices.

### DETAILED DESCRIPTION

High bandwidth memory may incorporate data lines to enable high-speed communications between the high bandwidth memory and a processor. High bandwidth memory may use a relatively wide memory interface to achieve a relatively high bandwidth. For example, a high bandwidth memory stack may have a 1024-bit wide interface. The high bandwidth memory may be associated with a data bus, which may be split into multiple channels, where each channel may have its own set of data lines. Through-silicon vias (TSVs) may serve as data lines between layers within the high bandwidth memory stack. The TSVs may connect the high bandwidth memory stack to a silicon interposer, which may route data to the processor.

High bandwidth memory, due to its intricate structure, may experience data line failures and/or defective lanes, which may be based on TSV defects, interposer faults, manufacturing variability, signal integrity issues, and/or wear over time. High bandwidth memory may incorporate built-in repair and redundancy mechanisms to handle defective data lines or lanes. For example, high bandwidth memory may support spare TSVs and data lanes. High bandwidth memory may be designed with redundant TSVs and/or data lanes. When a specific TSV that carries data fails, the data may be rerouted through an alternate TSV. High bandwidth memory may support error-correcting code, which may prevent minor data corruption due to faulty data lanes. High bandwidth memory may employ redundant memory banks. For example, the high bandwidth memory stack may include multiple independent memory banks within its channels, where some memory banks act as spare banks that are able to replace defective memory banks. Defective data lanes and TSVs may be detected and mapped during manufacturing. A manufacturer may configure redundancy and spare lanes to ensure that the high bandwidth memory is fully functional. High bandwidth memory may include a controller that supports real-time lane remapping, which may involve reassigning data transfer to alternate TSVs. The real-time lane remapping may occur at the firmware or hardware level.

High bandwidth memory may be associated with a plurality of data lines and/or lanes, which may be responsible for connecting the high bandwidth memory to a host device, such as the processor. For example, each lane may carry a portion of total data. Since certain lanes may be prone to failure, high bandwidth memory may support remapping (or repairing) broken data bus lanes. The remapping (or repairing) of lanes may increase a system level reliability. The remapping (or repairing) of lanes may be based on a lane repair block, which may be responsible for fixing lanes and/or an internal logic. When a specific lane is broken, the broken lane may be due to an error in the high bandwidth memory, the processor, or in the lane itself. However, the lane repair block may only be applied at a certain location of the high bandwidth memory, such that lane issues that are present before the lane repair block is applied may not be detected. In other words, in some cases, lane remapping (or repairing) may only fix lane issues after a certain point, where lane issues that occur prior to the lane repair block may be unable to be fixed, thereby degrading an overall system performance.

In some implementations, a memory device, such as a memory device associated with high bandwidth memory, may include a lane repair block. The memory device, using the lane repair block, may detect that a lane of the memory device is associated with a lane failure. The lane repair block may be employed prior to a first physical (PHY) latch that is between a TSV associated with the memory device and a data queue (DQ) pad associated with the memory device. The first PHY latch may be followed by a second PHY latch and a third PHY latch that are between the TSV and the DQ pad. The lane repair block may detect the lane failure based on a testing mechanism. The lane failure may be due to a variety of potential issues, such as timing and synchronization problems, signal integrity problems, overdrive, underdrive, latch setup and hold time violations, thermal effects, and/or aging and degradation. The memory device may map, using the lane repair block, the lane associated with the lane failure to an alternate lane associated with one or more alternate blocks.

In some implementations, the lane failure may be based on the first PHY latch, in which case the alternate lane may avoid the first PHY latch. The lane associated with the lane failure may include the first PHY latch, the second PHY latch, and the third PHY latch. The lane associated with the lane failure may include a DQ read (RD) first-in first-out (FIFO) block, a multiplexer block, and a parallel-to-serial conversion block. The alternate lane may include a first alternate PHY latch, a second alternate PHY latch, and a third alternate PHY latch. The alternate lane may include an alternate DQ RD FIFO block, an alternate multiplexer block, and an alternate parallel-to-serial conversion block. In some implementations, the lane repair block may be employed after a TSV receiver that is between the TSV and the DQ pad. The lane repair block may be employed after a TSV repair block that is between the TSV and the DQ pad. The lane repair block may be employed after a re-driver block that is between the TSV and the DQ pad.

In some implementations, by incorporating the lane repair block prior to the first PHY latch, the lane repair block may be able to detect lane failures that occur prior to the first PHY latch, which may allow the memory device to map the lane to the alternative lane. The alternative lane may include the first alternate PHY latch, the second alternate PHY latch, and the third alternate PHY latch. By employing the lane repair block prior to the first PHY latch, instead of after the third PHY latch, the memory device may be able to detect lane failures earlier in time and perform mitigation accordingly. The memory device, via the lane repair block, may be able to detect lane failures that are associated with PHY latches, as opposed to only being able to detect lane failures associated with a DQ RD FIFO block, a multiplexer block, and/or a parallel-to-serial conversion block. The memory device, using the lane repair block, may be able to remap downstream blocks with increased system level reliability, thereby improving an overall system performance.

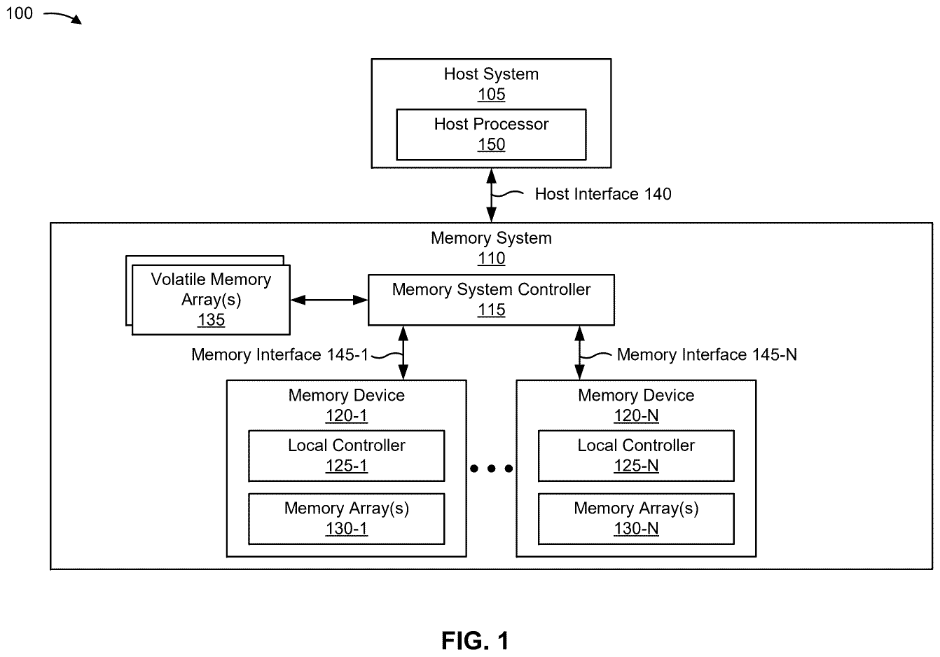

FIG. 1 is a diagram illustrating an example system 100 capable of repairing lanes associated with memory devices. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to detect, using a lane repair block, that a lane of the memory device is associated with a lane failure, wherein the lane repair block is employed prior to a first PHY latch that is between a TSV associated with the memory device and a DQ pad associated with the memory device; and map, using the lane repair block, the lane associated with the lane failure to an alternate lane associated with one or more alternate blocks.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

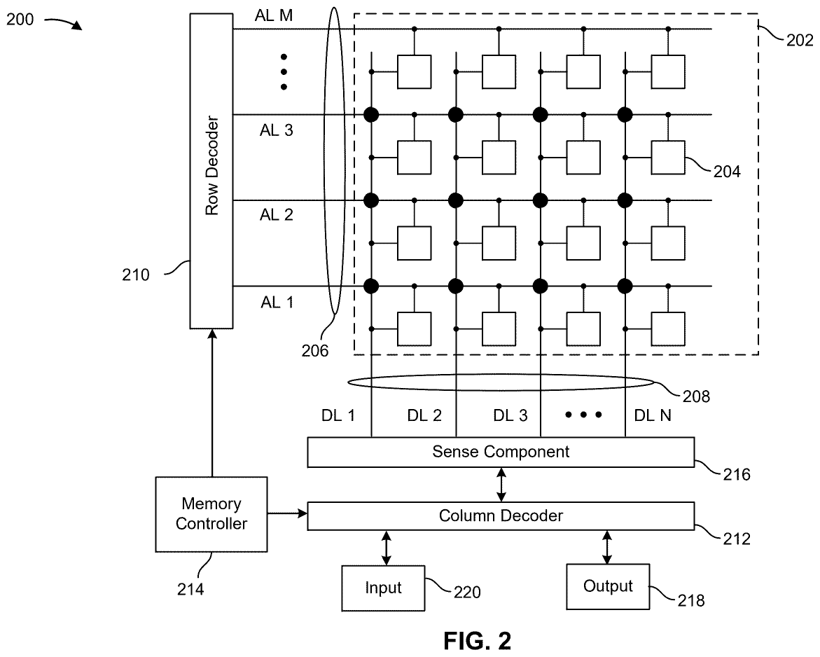

FIG. 2 is a diagrammatic view of an example memory device 200. The memory device 200 may include a memory array 202 that includes multiple memory cells 204. A memory cell 204 is programmable or configurable into a data state of multiple data states (e.g., two or more data states). For example, a memory cell 204 may be set to a particular data state at a particular time, and the memory cell 204 may be set to another data state at another time. A data state may correspond to a value stored by the memory cell 204. The value may be a binary value, such as a binary 0 or a binary 1, or may be a fractional value, such as 0.5, 1.5, or the like. A memory cell 204 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 204 by activating or selecting the appropriate access line 206 (shown as access lines AL 1 through AL M) and digit line 208 (shown as digit lines DL 1 through DL N). An access line 206 may also be referred to as a “row line” or a “word line,” and a digit line 208 may also be referred to a “column line” or a “bit line.” Activating or selecting an access line 206 or a digit line 208 may include applying a voltage to the respective line. An access line 206 and/or a digit line 208 may comprise, consist of, or consist essentially of a conductive material, such as a metal (e.g., copper, aluminum, gold, titanium, or tungsten) and/or a metal alloy, among other examples. In FIG. 2, each row of memory cells 204 is connected to a single access line 206, and each column of memory cells 204 is connected to a single digit line 208. By activating one access line 206 and one digit line 208 (e.g., applying a voltage to the access line 206 and digit line 208), a single memory cell 204 may be accessed at (e.g., is accessible via) the intersection of the access line 206 and the digit line 208. The intersection of the access line 206 and the digit line 208 may be called an “address” of a memory cell 204.

In some implementations, the logic storing device of a memory cell 204, such as a capacitor, may be electrically isolated from a corresponding digit line 208 by a selection component, such as a transistor. The access line 206 may be connected to and may control the selection component. For example, the selection component may be a transistor, and the access line 206 may be connected to the gate of the transistor. Activating the access line 206 results in an electrical connection or closed circuit between the capacitor of a memory cell 204 and a corresponding digit line 208. The digit line 208 may then be accessed (e.g., is accessible) to either read from or write to the memory cell 204.

A row decoder 210 and a column decoder 212 may control access to memory cells 204. For example, the row decoder 210 may receive a row address from a memory controller 214 and may activate the appropriate access line 206 based on the received row address. Similarly, the column decoder 212 may receive a column address from the memory controller 214 and may activate the appropriate digit line 208 based on the column address.

Upon accessing a memory cell 204, the memory cell 204 may be read (e.g., sensed) by a sense component 216 to determine the stored data state of the memory cell 204. For example, after accessing the memory cell 204, the capacitor of the memory cell 204 may discharge onto its corresponding digit line 208. Discharging the capacitor may be based on biasing, or applying a voltage, to the capacitor. The discharging may induce a change in the voltage of the digit line 208, which the sense component 216 may compare to a reference voltage (not shown) to determine the stored data state of the memory cell 204. For example, if the digit line 208 has a higher voltage than the reference voltage, then the sense component 216 may determine that the stored data state of the memory cell 204 corresponds to a first value, such as a binary 1. Conversely, if the digit line 208 has a lower voltage than the reference voltage, then the sense component 216 may determine that the stored data state of the memory cell 204 corresponds to a second value, such as a binary 0. The detected data state of the memory cell 204 may then be output (e.g., via the column decoder 212) to an output component 218 (e.g., a data buffer). A memory cell 204 may be written (e.g., set) by activating the appropriate access line 206 and digit line 208. The column decoder 212 may receive data, such as input from input component 220, to be written to one or more memory cells 204. A memory cell 204 may be written by applying a voltage across the capacitor of the memory cell 204.

The memory controller 214 may control the operation (e.g., read, write, re-write, refresh, and/or recovery) of the memory cells 204 via the row decoder 210, the column decoder 212, and/or the sense component 216. The memory controller 214 may generate row address signals and column address signals to activate the desired access line 206 and digit line 208. The memory controller 214 may also generate and control various voltages used during the operation of the memory array 202.

As indicated above, FIG. 2 is provided as an example. Other examples may differ from what is described with respect to FIG. 2.

High bandwidth memory is a type of high-performance DRAM designed to provide higher bandwidth as compared to DDR memory. High bandwidth memory may employ stacking multiple memory chips vertically and connecting the multiple memory chips using an interconnect, such as TSVs. High bandwidth memory may provide greater memory bandwidth than DDR memory due to its wide memory interface and stacked architecture. High bandwidth memory may provide lower power consumption than DDR memory due to its lower operating voltage and shorter signal paths. High bandwidth memory may utilize vertically stacked DRAM dies connected with TSVs, which may reduce the need for a large memory bus. High bandwidth memory may reduce space on a printed circuit board (PCB) since the high bandwidth memory is directly integrated with the processor. High bandwidth memory may be used in high-performance applications. For example, high bandwidth memory may be used in graphical processing units (GPUs), artificial intelligence (AI) accelerators, field-programmable gate arrays (FPGAs), or high-performance computing (HPC) workloads.

High bandwidth memory (HBM) (first generation) may support approximately 1 gigabits per second (Gbps) per pin and approximately 128 gigabytes per second (GB/s) bandwidth per stack. HBM2 may support approximately 2 Gbps per pin and up to approximately 256 GB/s bandwidth per stack. HBM 3 may support approximately 6. 4Gbps per pin and approximately 820 GB/s bandwidth per stack. HBM 4 may support approximately 1 terabyte per second (TB/s) bandwidth per stack.

High bandwidth memory may stack multiple DRAM dies vertically on top of each other, unlike DDR memory in which memory chips are laid out horizontally. Such stacking may increase memory density while reducing a physical footprint. Each stack may include multiple DRAM dies (e.g., 4, 8, or 12 dies per stack) and a base logic die at the bottom, which may manage communication between the stacked memory and the processor. High bandwidth memory may use TSVs to connect the vertically stacked DRAM layers. The TSVs may be vertical connections etched through silicon wafers, which may allow signals to pass directly between layers instead of routing the signals around a stack, which may reduce latency and power consumption. The TSVs may provide numerous high-speed interconnects between different layers. Micro bumps may be solder connections between stacked dies that maintain signal integrity. High bandwidth memory may achieve the high bandwidth by using a relatively wide memory interface as compared to DDR memory. For example, each stack may be 1024 bits wide, and multiple stacks may be combined for even greater bandwidth. The relatively wide memory interface may allow high bandwidth memory to transfer more data per clock cycle at lower speeds, which may improve efficiency. High bandwidth memory may be placed close to the processor using a silicon interposer, which is a layer that connects the processor to the high bandwidth memory with high-speed traces. Shorter distances between the high bandwidth memory and the processor may reduce data travel time, which may improve latency and power efficiency. High bandwidth memory may be integrated with the processor, unlike off-chip memory, which may enable faster data transfer.

In high bandwidth memory, data lines may enable high-speed communications between the high bandwidth memory and a processor. High bandwidth memory may use a wide memory interface to achieve high bandwidth. A high bandwidth memory stack (e.g., a three-dimensional stacked DRAM module) may have a 1024-bit wide interface. A data bus may be split into multiple channels. The high bandwidth memory stack may have 8 to 16 independent channels, where each channel may have its own set of data lines. TSVs may serve as data lines between layers within the high bandwidth memory stack. The TSVs may connect the high bandwidth memory stack to a silicon interposer, which may route data to the processor.

High bandwidth memory, due to its intricate structure, may experience data line failures and/or defective lanes, which may be based on TSV defects, interposer faults, manufacturing variability, signal integrity issues, and/or wear over time. High bandwidth memory may incorporate built-in repair and redundancy mechanisms to handle defective data lines or lanes. For example, high bandwidth memory may support spare TSVs and data lanes. High bandwidth memory may be designed with redundant TSVs and/or data lanes. When a specific TSV that carries data fails, the data may be rerouted through an alternate TSV. High bandwidth memory may support error-correcting code, which may prevent minor data corruption due to faulty data lanes.

High bandwidth memory may employ redundant memory banks. For example, the high bandwidth memory stack may include multiple independent memory banks within its channels, where some memory banks act as spare banks that are able to replace defective memory banks. Defective data lanes and TSVs may be detected and mapped during manufacturing. A manufacturer may configure redundancy and spare lanes to ensure that the high bandwidth memory is fully functional. High bandwidth memory may include a controller that supports real-time lane remapping, which may involve reassigning data transfer to alternate TSVs. The real-time lane remapping may occur at the firmware or hardware level.

High bandwidth memory may be associated with a plurality of data lines and/or lanes, which may be responsible for connecting the high bandwidth memory to a host device, such as the processor. A data line may be a physical or logical connection that carries data between two points, where a lane may be a collection of one or more data lines that work together to transmit data. For example, each lane may carry a portion of total data. Since certain lanes may be prone to failure, high bandwidth memory may support remapping (or repairing) broken data bus lanes. The remapping (or repairing) of lanes may increase a system level reliability. The remapping (or repairing) of lanes may be based on a lane repair block, which may be responsible for fixing lanes and/or an internal logic. When a specific lane is broken, the broken lane may be due to an error in the high bandwidth memory, the processor, or in the lane itself. However, the lane repair block may only be applied at a certain location of the high bandwidth memory, such that lane issues that are present before the lane repair block is applied may not be detected. In other words, in some cases, lane remapping (or repairing) may only fix lane issues after a certain point, where lane issues that occur prior to the lane repair block may be unable to be fixed, thereby degrading an overall system performance.

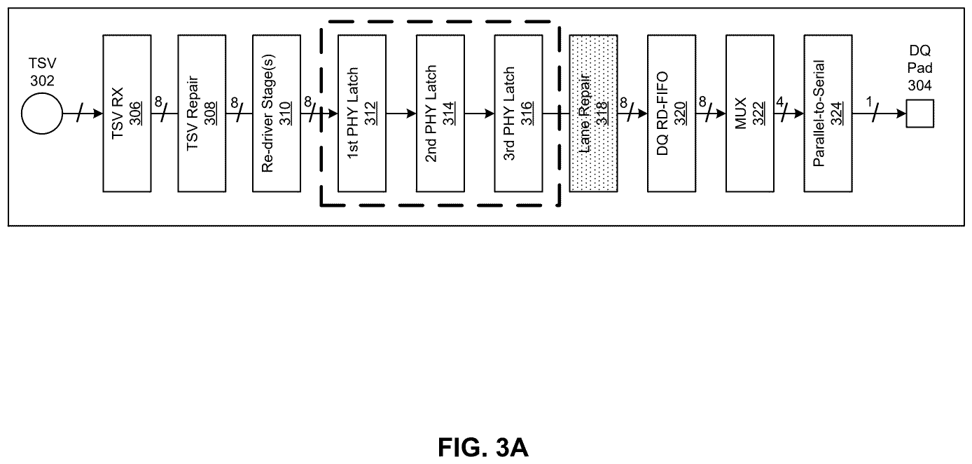

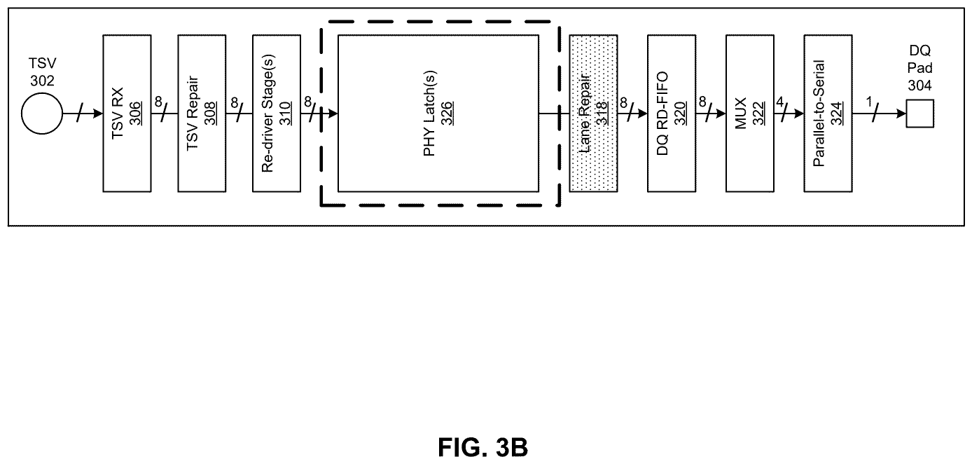

FIG. 3A-3B are diagrams of examples 300 of existing data flows with lane repair. The operations described in connection with FIGS. 3A-3B may be performed by the memory system 110 and/or one or more components of the memory system 110, such as the memory system controller 115, one or more memory devices 120, and/or one or more local controllers 125.

As shown in FIG. 3A, in a read data flow with lane repair, high bandwidth memory may be associated with a TSV 302, which may be a vertical electrical connection that passes through silicon wafers or dies and which may allow direct communication between stacked layers of memory. The TSV 302 may be associated with 8 data lines/lanes. The high bandwidth memory may be associated with a DQ pad 304 (or data pin). The DQ pad 304 may be a physical interface point on the high bandwidth memory that transmits and receives data. The DQ pad 304 may be associated with a data bus. The DQ pad 304 may be associated with data transfer. The DQ pad 304 may be responsible for sending and receiving data bits between memory and a processor. The DQ pad 304 may be connected through an interposer, which may support high-speed, wide-bus data transfer.

The high bandwidth memory may be associated with a plurality of components between the TSV 302 and the DQ pad 304. The plurality of components may include a TSV receiver (RX) 306. The TSV RX 306 may be a receiver circuit that processes signals transmitted through the TSV 302. For example, the TSV RX 306 may amplify, equalize, and/or process the signals transmitted through the TSV 302. The plurality of components may include a TSV repair block 308. The TSV repair block 308 may be responsible for repairing or mitigating defects in the TSV 302. For example, the TSV repair block 308 may activate a redundant TSV to replace a faulty TSV, such that data may be rerouted to the redundant TSV. The plurality of components may include one or more re-driver stages 310. A re-driver stage 310 may be responsible for signal conditioning, which may compensate for signal degradation. The plurality of components may include a first PHY latch 312. A PHY latch may be associated with a retiming of data from the TSV 302. A PHY-to-TSV routing may be a relatively long routing, so an alignment of the data may be needed when the data arrives at a PHY area. The first PHY latch 312 may help with data synchronization, signal integrity, and/or timing control. The first PHY latch 312 may temporarily hold (or latch) data to ensure proper timing alignment between different clock domains. The first PHY latch 312 may ensure that data is captured precisely on a rising edge or a falling edge of a clock signal. The plurality of components may include a second PHY latch 314, which may perform similar functions as the first PHY latch 312. The plurality of components may include a third PHY latch 316, which may perform similar functions as the first PHY latch 312 and/or the second PHY latch 314. The third PHY latch 316 may incorporate data bus inversion (DBI), which may reduce a number of bit transitions on the data bus, thereby lowering power consumption and reducing signal noise. A DBI bit may be latched and sent along data to indicate if an inversion occurred.

High bandwidth memory may have a massively parallel interface with 1024 data lines per stack, so multiple PHY latches may be used to handle such high-speed, high-bandwidth data transfer. The multiple PHY latches may enable proper timing alignment and improve signal integrity across TSV-based high bandwidth memory stacks. The multiple PHY latches may be used to synchronize data across multiple lanes (data bits per channel). High bandwidth memory may use multiple independent channels, where each channel may have 128-bit wide data lanes, which may require multiple PHY latches to align signals. The multiple PHY latches may ensure data alignment between a memory controller and high bandwidth memory die stacks, which may reduce timing mismatches.

The plurality of components may include a lane repair block 318. The lane repair block 318 may detect a broken lane and perform a dynamic lane remapping. The lane repair block 318 may monitor a health of a plurality of lanes. When a lane failure is detected, the lane repair block 318 may remap data through available healthy lanes or use alternate paths for communication. The lane repair block 318 may be capable of repairing a given lane, which may be effective for blocks after the lane repair block 318. The lane repair block 318 may not impact blocks that occur prior to the lane repair block 318. The lane repair block 318 may be associated with 8 data lines/lanes.

The plurality of components may include a DQ RD FIFO block 320. The DQ RD FIFO block 320 may be a buffer that temporarily stores data read from memory and manages the flow of data from memory. The DQ RD FIFO block 320 may be used for a read operation. The DQ RD FIFO block 320 may be responsible for buffering read data, ensuring timing alignment, preventing data loss, and/or improving throughput and latency. The DQ RD FIFO block 320 may be associated with 8 data lines/lanes. The plurality of components may include a multiplexer (MUX) block 322, such as an 8:4 MUX. The multiplexer block 322 may create 4 data lines/lanes from the 8 data lines/lanes. In this example, the multiplexer block 322 may take 8 input lines and select 4 output lines. The plurality of components may include a parallel-to-serial (Par2Ser) conversion block 324, which may be responsible for converting parallel data into serial data. The parallel-to-serial conversion block 324 may take multiple parallel input bits and convert them into a single data stream. In this example, the parallel-to-serial conversion block 324 may take 4 data lines/lanes and create the single data stream (e.g., 1 data line/lane). The single data stream may be provided to the DQ pad 304.

In one example, when the lane repair block 318 is employed to repair a faulty lane, subsequent blocks may be adapted. For example, when the lane repair block 318 is employed to repair the faulty lane, the DQ RD FIFO block 320, the multiplexer block 322, and/or the parallel-to-serial conversion block 324 may be replaced with different blocks, which may be based on a lane repair (remapping) performed by the lane repair block 318.

In this example, the lane repair block 318 may be employed after the first PHY latch 312, the second PHY latch 314, and the third PHY latch 316. The lane repair block may be employed prior to the DQ RD FIFO block 320, the multiplexer block 322, and the parallel-to-serial conversion block 324. While the lane repair block 318 may be capable of repairing a lane that is effective at blocks after the lane repair block 318 (e.g., the DQ RD FIFO block 320, the multiplexer block 322, and the parallel-to-serial conversion block 324), the lane repair block 318 may not be capable of fixing issues associated with the first PHY latch 312, the second PHY latch 314, and the third PHY latch 316. The first PHY latch 312, the second PHY latch 314, and the third PHY latch 316 may be affected by a variety of potential issues, such as timing and synchronization problems, signal integrity problems, overdrive, underdrive, latch setup and hold time violations, thermal effects, and/or aging and degradation. Such issues may effect a reliability and/or performance of the first PHY latch 312, the second PHY latch 314, and the third PHY latch 316. Other issues may include physical issues or electrical issues. An example of a physical issue may be a defect during manufacturing. An example of an electrical issue may be a marginal issue due to various conditions, such as temperature. However, since the lane repair block 318 is only deployed after the first PHY latch 312, the second PHY latch 314, and the third PHY latch 316, the lane repair block 318 may be unable to fix any issues associated with the first PHY latch 312, the second PHY latch 314, and the third PHY latch 316, which may degrade an overall system performance.

As shown in FIG. 3B, high bandwidth memory may be associated with a plurality of components, which may include one or more PHY latches 326. The one or more PHY latches 326 may be prior to the lane repair 318. The one or more PHY latches 326 may include the first PHY latch 312, the second PHY latch 314, and/or the third PHY latch 316.

As indicated above, FIGS. 3A-3B is provided as an example. Other examples may differ from what is described with regard to FIGS. 3A-3B.

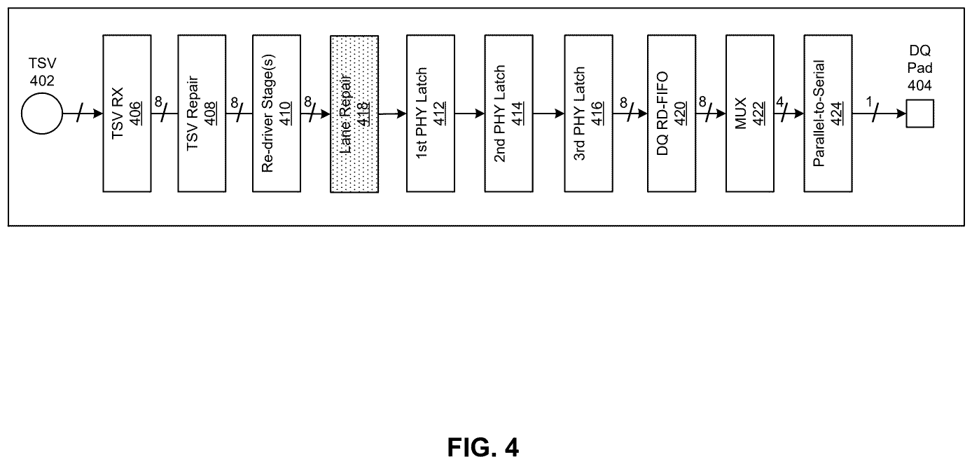

FIG. 4 is a diagram of an example 400 of lane repair prior to PHY latches. The operations described in connection with FIG. 4 may be performed by the memory system 110 and/or one or more components of the memory system 110, such as the memory system controller 115, one or more memory devices 120, and/or one or more local controllers 125.

As shown in FIG. 4, in a read data flow with lane repair, high bandwidth memory may be associated with a TSV 402, which may be a vertical electrical connection that passes through silicon wafers or dies and which may allow direct communication between stacked layers of memory. The TSV 402 may be associated with 8 data lines/lanes. The high bandwidth memory may be associated with a DQ pad 404 (or data pin). The DQ pad 404 may be a physical interface point on the high bandwidth memory that transmits and receives data. The DQ pad 404 may be associated with a data bus. The DQ pad 404 may be associated with data transfer. The DQ pad 404 may be responsible for sending and receiving data bits between memory and a processor. The DQ pad 404 may be connected through an interposer, which may support high-speed, wide-bus data transfer.

In some implementations, the high bandwidth memory may be associated with a plurality of components between the TSV 402 and the DQ pad 404. The plurality of components may include a TSV RX 406. The TSV RX 406 may be a receiver circuit that processes signals transmitted through the TSV 402. For example, the TSV RX 406 may amplify, equalize, and/or process the signals transmitted through the TSV 402. The plurality of components may include a TSV repair block 408. The TSV repair block 408 may be responsible for repairing or mitigating defects in the TSV 402. For example, the TSV repair block 408 may activate a redundant TSV to replace a faulty TSV, such that data may be rerouted to the redundant TSV. The plurality of components may include one or more re-driver stages 410. A re-driver stage 410 may be responsible for signal conditioning, which may compensate for signal degradation.

In some implementations, the plurality of components may include a lane repair block 418. The lane repair block 418 may detect a broken lane and perform a dynamic lane remapping. The lane repair block 418 may monitor a health of a plurality of lanes. When a lane failure is detected, the lane repair block 418 may remap data through available healthy lanes or use alternate paths for communication. The lane repair block 418 may be capable of repairing a given lane, which may be effective for blocks after the lane repair block 418. The lane repair block 418 may not impact blocks that occur prior to the lane repair block 418. The lane repair block 418 may be associated with 8 data lines/lanes. In this example, the lane repair block 418 may occur immediately after the re-driver stage 410. The lane repair block 418 may cover a majority of a PHY area, while the TSV repair block 408 may cover a majority of a TSV area.

In some implementations, the plurality of components may include a first PHY latch 412. The first PHY latch 412 may help with data synchronization, signal integrity, and/or timing control. The first PHY latch 412 may temporarily hold (or latch) data to ensure proper timing alignment between different clock domains. The first PHY latch 412 may ensure that data is captured precisely on a rising edge or a falling edge of a clock signal. The plurality of components may include a second PHY latch 414, which may perform similar functions as the first PHY latch 412. The plurality of components may include a third PHY latch 416, which may perform similar functions as the first PHY latch 412 and/or the second PHY latch 414. The third PHY latch 416 may incorporate DBI, which may reduce a number of bit transitions on the data bus, thereby lowering power consumption and reducing signal noise. A DBI bit may be latched and sent along data to indicate if an inversion occurred.

In some implementations, the high bandwidth memory may have a massively parallel interface with 1024 data lines per stack, so multiple PHY latches may be used to handle such high-speed, high-bandwidth data transfer. The multiple PHY latches may enable proper timing alignment and improve signal integrity across TSV-based high bandwidth memory stacks. The multiple PHY latches may be used to synchronize data across multiple lanes (data bits per channel). High bandwidth memory may use multiple independent channels, where each channel may have 128-bit wide data lanes, which may require multiple PHY latches to align signals. The multiple PHY latches may ensure data alignment between a memory controller and high bandwidth memory die stacks, which may reduce timing mismatches.

In some implementations, the plurality of components may include a DQ RD FIFO block 420. The DQ RD FIFO block 420 may be a buffer that temporarily stores data read from memory and manages the flow of data from memory. The DQ RD FIFO block 420 may be used for a read operation. The DQ RD FIFO block 420 may be responsible for buffering read data, ensuring timing alignment, preventing data loss, and/or improving throughput and latency. The DQ RD FIFO block 420 may be associated with 8 data lines/lanes. The plurality of components may include a multiplexer block 422, such as an 8:4 MUX. The multiplexer block 422 may create 4 data lines/lanes from the 8 data lines/lanes. In this example, the multiplexer block 422 may take 8 input lines and select 4 output lines. The plurality of components may include a parallel-to-serial conversion block 424, which may be responsible for converting parallel data into serial data. The parallel-to-serial conversion block 424 may take multiple parallel input bits and convert them into a single data stream. In this example, the parallel-to-serial conversion block 424 may take 4 data lines/lanes and create the single data stream (e.g., 1 data line/lane). The single data stream may be provided to the DQ pad 404.

In some implementations, when the lane repair block 418 is employed to repair a faulty lane, subsequent blocks may be adapted. For example, when the lane repair block 418 is employed to repair the faulty lane, the first PHY latch 412, the second PHY latch 414, the third PHY latch 416, the DQ RD FIFO block 420, the multiplexer block 422, and/or the parallel-to-serial conversion block 424 may be replaced with different blocks, which may be based on a lane repair (remapping) performed by the lane repair block 418. In some implementations, the lane repair block 418 may be employed prior to the first PHY latch 412, the second PHY latch 414, and the third PHY latch 416, such that the lane repair block 418 may be able to fix issues associated with the first PHY latch 412, the second PHY latch 414, and/or the third PHY latch 416. The first PHY latch 412, the second PHY latch 414, and/or the third PHY latch 416 may be affected by a variety of potential issues, such as timing and synchronization problems, signal integrity problems, overdrive, underdrive, latch setup and hold time violations, thermal effects, and/or aging and degradation. Such issues may effect a reliability and/or performance of the first PHY latch 412, the second PHY latch 414, and the third PHY latch 416. By deploying the lane repair block 418 prior to the first PHY latch 412, the second PHY latch 414, and the third PHY latch 416, the lane repair block 418 may be able to fix any issues associated with the first PHY latch 412, the second PHY latch 414, and the third PHY latch 416, which may improve an overall system performance.

In some implementations, the lane repair block 418 may be prior to the first PHY latch 412, instead of being after the third PHY latch 416. In this example, when the lane repair block 418 performs a lane repair (or remapping), the first PHY latch 412, the second PHY latch 414, and the third PHY latch 416 may be replaced with different PHY latches. By deploying the lane repair block 418 prior to the first PHY latch 412, the TSV repair block 408 may handle issues associated with a TSV area and the lane repair block 418 may handle issues associated with a PHY area.

In some implementations, the plurality of components may include a single PHY latch. The lane repair block 418 may be deployed prior to the single PHY latch, as opposed to being deployed after the single PHY latch. In some implementations, the plurality of components may include two or more PHY latches. The lane repair block 418 may be deployed prior to the two or more PHY latches, as opposed to being deployed after the two or more PHY latches.

As indicated above, FIG. 4 is provided as an example. Other examples may differ from what is described with regard to FIG. 4.

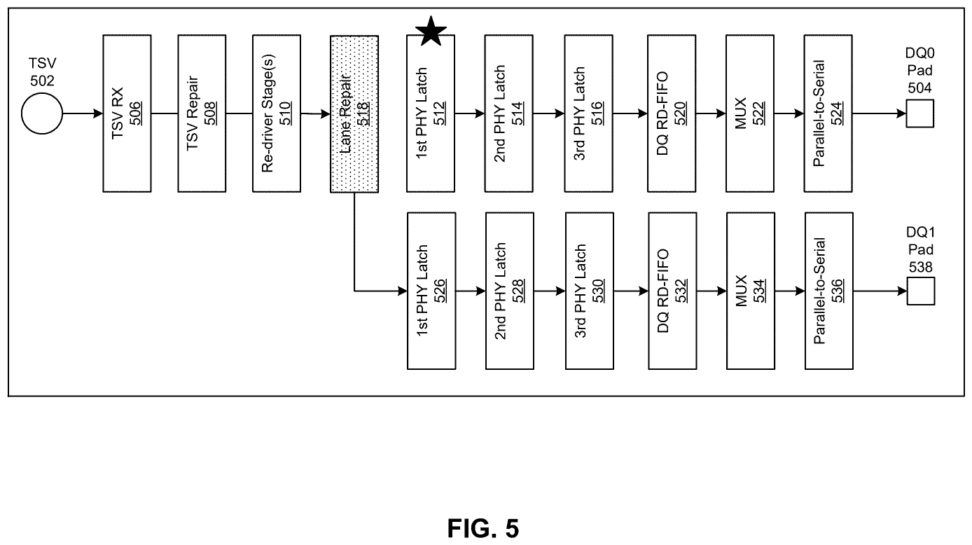

FIG. 5 is a diagram of an example 500 associated with lane repairing. The operations described in connection with FIG. 5 may be performed by the memory system 110 and/or one or more components of the memory system 110, such as the memory system controller 115, one or more memory devices 120, and/or one or more local controllers 125.

As shown in FIG. 5, in a read data flow with lane repair, high bandwidth memory may be associated with a TSV 502. The high bandwidth memory may be associated with a first DQ (DQ0) pad 504 (or data pin). The high bandwidth memory may be associated with a plurality of components between the TSV 502 and the DQ pad 504. The plurality of components may include a TSV RX 506, a TSV repair block 508, and one or more re-driver stages 510. The plurality of components may include a lane repair block 518. The lane repair block 518 may detect a broken lane and perform a dynamic lane remapping. The lane repair block 518 may monitor a health of a plurality of lanes. When a lane failure is detected, the lane repair block 518 may remap data through available healthy lanes or use alternate paths for communication. The lane repair block 518 may be capable of repairing a given lane, which may be effective for blocks after the lane repair block 518. The lane repair block 418 may not impact blocks that occur prior to the lane repair block 518.

In some implementations, the lane repair block 518 may detect an issue associated with a first PHY latch 512. In this example, a second PHY latch 514, a third PHY latch 516, a DQ RD FIFO block 520, a multiplexer block 522, and/or a parallel-to-serial conversion block 524, which may be associated with the first PHY latch 512, may not be used. Rather, the lane repair block 518 may determine to use alternative blocks based on a lane remapping. The lane repair block 518 may cause a first PHY latch 526, a second PHY latch 528, a third PHY latch 530, a DQ RD FIFO block 532, a multiplexer block 534, a parallel-to-serial conversion block 536, and a second DQ (DQ1) pad 538 to be used. The first PHY latch 526, the second PHY latch 528, the third PHY latch 530, the DQ RD FIFO block 532, the multiplexer block 534, the parallel-to-serial conversion block 536, and the second DQ (DQ1) pad 538 may be associated with an alternate path, which may be used when the issue is detected in the first PHY latch 512.

In some implementations, when the lane repair block 518 is deployed after the third PHY latch 516, the issue associated with the first PHY latch 512 may be unable to be repaired. When the lane repair block 518 is deployed prior to the first PHY latch 512, the issue associated with the first PHY latch 512 may be mitigated by remapping to the first PHY latch 526, the second PHY latch 528, the third PHY latch 530, the DQ RD FIFO block 532, the multiplexer block 534, the parallel-to-serial conversion block 536, and the second DQ (DQ1) pad 538. By deploying the lane repair block 518 prior to the first PHY latch 512 instead of after the third PHY latch 516, the lane repair block 518 may be able to remap an increased number of downstream blocks. The lane repair block 518 may provide increased coverage in remapping the downstream blocks, which may provide additional coverage in repairing an internal circuit, and which may increase a system level reliability.

In some implementations, when the lane repair block 518 is moved prior to the first PHY latch 512, an area penalty may arise. One more set of circuit may be needed for a repairing lane. In the past, area was more important than reliability because defects or other issues were less likely to occur. However, when finer processes are used, these kind of issues may be more likely. As a result, the lane repair block 518 may be moved in order to have larger coverage.

As indicated above, FIG. 5 is provided as an example. Other examples may differ from what is described with regard to FIG. 5.

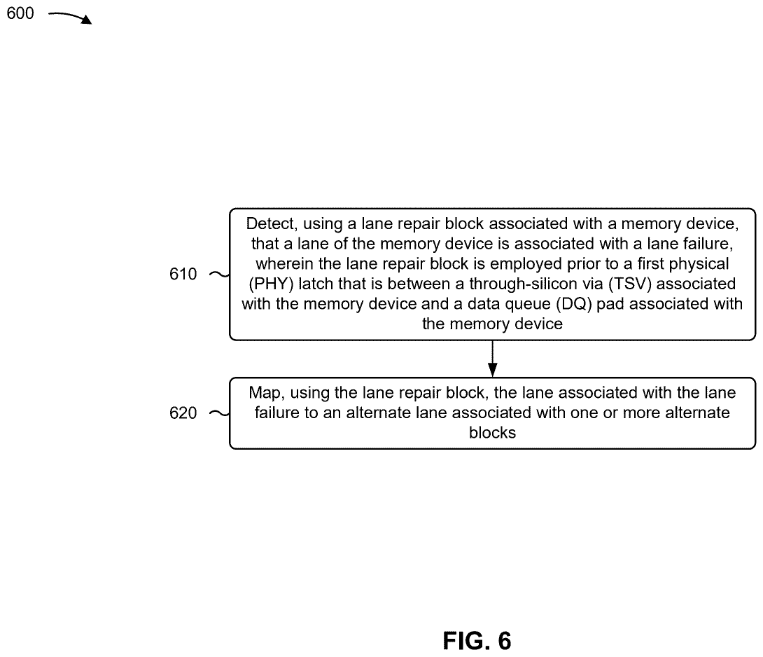

FIG. 6 is a flowchart of an example method 600 associated with repairing lanes in memory devices. In some implementations, a memory device (e.g., the memory device 120) may perform or may be configured to perform the method 600. In some implementations, another device or a group of devices separate from or including the memory device (e.g., the system 100) may perform or may be configured to perform the method 600. Additionally, or alternatively, one or more components of the memory device may perform or may be configured to perform the method 600. Thus, means for performing the method 600 may include the memory device and/or one or more components of the memory device. Additionally, or alternatively, a non-transitory computer-readable medium may store one or more instructions that, when executed by the memory device, cause the memory device to perform the method 600.

As shown in FIG. 6, the method 600 may include detecting, using a lane repair block associated with a memory device, that a lane of the memory device is associated with a lane failure, wherein the lane repair block is employed prior to a first PHY latch that is between a TSV associated with the memory device and a DQ pad associated with the memory device (block 610). As further shown in FIG. 6, the method 600 may include mapping, using the lane repair block, the lane associated with the lane failure to an alternate lane associated with one or more alternate blocks (block 620).

The method 600 may include additional aspects, such as any single aspect or any combination of aspects described below and/or described in connection with one or more other methods or operations described elsewhere herein.

In a first aspect, the first PHY latch is followed by a second PHY latch and a third PHY latch that are between the TSV and the DQ pad.

In a second aspect, alone or in combination with the first aspect, the lane failure is based on the first PHY latch, and the alternate lane avoids the first PHY latch.

In a third aspect, alone or in combination with one or more of the first and second aspects, the lane associated with the lane failure includes the first PHY latch, a second PHY latch, and a third PHY latch, and the alternate lane includes a first alternate PHY latch, a second alternate PHY latch, and a third alternate PHY latch.

In a fourth aspect, alone or in combination with one or more of the first through third aspects, the lane repair block is employed after a TSV receiver that is between the TSV and the DQ pad.

In a fifth aspect, alone or in combination with one or more of the first through fourth aspects, the lane repair block is employed after a TSV repair block that is between the TSV and the DQ pad.

In a sixth aspect, alone or in combination with one or more of the first through fifth aspects, the lane repair block is employed after a re-driver block that is between the TSV and the DQ pad.

In a seventh aspect, alone or in combination with one or more of the first through sixth aspects, the lane associated with the lane failure includes a DQ RD FIFO block, a multiplexer block, and a parallel-to-serial conversion block, and the alternate lane includes an alternate DQ RD FIFO block, an alternate multiplexer block, and an alternate parallel-to-serial conversion block.

In an eighth aspect, alone or in combination with one or more of the first through seventh aspects, the memory device is associated with high bandwidth memory.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a memory device includes one or more components configured to: detect, using a lane repair block, that a lane of the memory device is associated with a lane failure, wherein the lane repair block is employed prior to a first PHY latch that is between a TSV associated with the memory device and a DQ pad associated with the memory device; and map, using the lane repair block, the lane associated with the lane failure to an alternate lane associated with one or more alternate blocks.

In some implementations, a method includes detecting, using a lane repair block associated with a memory device, that a lane of the memory device is associated with a lane failure, wherein the lane repair block is employed prior to a first PHY latch that is between a TSV associated with the memory device and a DQ pad associated with the memory device; and mapping, using the lane repair block, the lane associated with the lane failure to an alternate lane associated with one or more alternate blocks.

In some implementations, an apparatus includes means for detecting that a lane of a memory device is associated with a lane failure, wherein a lane repair block is employed prior to a first PHY latch that is between a TSV associated with the memory device and a DQ pad associated with the memory device; and means for mapping the lane associated with the lane failure to an alternate lane associated with one or more alternate blocks.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
detect, using a lane repair block, that a lane of the memory device is associated with a lane failure, wherein the lane repair block is employed prior to a first physical (PHY) latch that is between a through-silicon via (TSV) associated with the memory device and a data queue (DQ) pad associated with the memory device; and
map, using the lane repair block, the lane associated with the lane failure to an alternate lane associated with one or more alternate blocks.

2. The memory device of claim 1, wherein the first PHY latch is followed by a second PHY latch and a third PHY latch that are between the TSV and the DQ pad.

3. The memory device of claim 1, wherein the lane failure is based on the first PHY latch, and wherein the alternate lane avoids the first PHY latch.

4. The memory device of claim 1, wherein the lane associated with the lane failure includes the first PHY latch, a second PHY latch, and a third PHY latch, and wherein the alternate lane includes a first alternate PHY latch, a second alternate PHY latch, and a third alternate PHY latch.

5. The memory device of claim 1, wherein the lane repair block is employed after a TSV receiver that is between the TSV and the DQ pad.

6. The memory device of claim 1, wherein the lane repair block is employed after a TSV repair block that is between the TSV and the DQ pad.

7. The memory device of claim 1, wherein the lane repair block is employed after a re-driver block that is between the TSV and the DQ pad.

8. The memory device of claim 1, wherein the lane associated with the lane failure includes a DQ read (RD) first-in first-out (FIFO) block, a multiplexer block, and a parallel-to-serial conversion block, and wherein the alternate lane includes an alternate DQ RD FIFO block, an alternate multiplexer block, and an alternate parallel-to-serial conversion block.

9. The memory device of claim 1, wherein the memory device is associated with high bandwidth memory.

10. A method, comprising:
detecting, using a lane repair block associated with a memory device, that a lane of the memory device is associated with a lane failure, wherein the lane repair block is employed prior to a first physical (PHY) latch that is between a through-silicon via (TSV) associated with the memory device and a data queue (DQ) pad associated with the memory device; and
mapping, using the lane repair block, the lane associated with the lane failure to an alternate lane associated with one or more alternate blocks.

11. The method of claim 10, wherein the first PHY latch is followed by a second PHY latch and a third PHY latch that are between the TSV and the DQ pad.

12. The method of claim 10, wherein the lane failure is based on the first PHY latch, and wherein the alternate lane avoids the first PHY latch.

13. The method of claim 10, wherein the lane associated with the lane failure includes the first PHY latch, a second PHY latch, and a third PHY latch, and wherein the alternate lane includes a first alternate PHY latch, a second alternate PHY latch, and a third alternate PHY latch.

14. The method of claim 10, wherein the lane repair block is employed after a TSV receiver that is between the TSV and the DQ pad.

15. The method of claim 10, wherein the lane repair block is employed after a TSV repair block that is between the TSV and the DQ pad.

16. The method of claim 10, wherein the lane repair block is employed after a re-driver block that is between the TSV and the DQ pad.

17. The method of claim 10, wherein the lane associated with the lane failure includes a DQ read (RD) first-in first-out (FIFO) block, a multiplexer block, and a parallel-to-serial conversion block, and wherein the alternate lane includes an alternate DQ RD FIFO block, an alternate multiplexer block, and an alternate parallel-to-serial conversion block.

18. The method of claim 10, wherein the memory device is associated with high bandwidth memory.

19. An apparatus, comprising:
means for detecting that a lane of a memory device is associated with a lane failure, wherein a lane repair block is employed prior to a first physical (PHY) latch that is between a through-silicon via (TSV) associated with the memory device and a data queue (DQ) pad associated with the memory device; and
means for mapping the lane associated with the lane failure to an alternate lane associated with one or more alternate blocks.

20. The apparatus of claim 19, wherein the first PHY latch is followed by a second PHY latch and a third PHY latch that are between the TSV and the DQ pad.

21. The apparatus of claim 19, wherein the lane failure is based on the first PHY latch, and wherein the alternate lane avoids the first PHY latch.

22. The apparatus of claim 19, wherein the lane associated with the lane failure includes the first PHY latch, a second PHY latch, and a third PHY latch, and wherein the alternate lane includes a first alternate PHY latch, a second alternate PHY latch, and a third alternate PHY latch.

23. The apparatus of claim 19, wherein the lane repair block is employed after a TSV receiver that is between the TSV and the DQ pad, wherein the lane repair block is employed after a TSV repair block that is between the TSV and the DQ pad, and wherein the lane repair block is employed after a re-driver block that is between the TSV and the DQ pad.

24. The apparatus of claim 19, wherein the lane associated with the lane failure includes a DQ read (RD) first-in first-out (FIFO) block, a multiplexer block, and a parallel-to-serial conversion block, and wherein the alternate lane includes an alternate DQ RD FIFO block, an alternate multiplexer block, and an alternate parallel-to-serial conversion block.

25. The apparatus of claim 19, wherein the memory device is associated with high bandwidth memory.
